(19) United States
(12) Patent Application Publication
(10) Pub. No.: US 2026/0029726 A1
(43) Pub. Date: Jan. 29, 2026

(54) METHOD OF OBTAINING POSITION OF EACH OF PLURALITY OF REGIONS ON SUBSTRATE, INFORMATION PROCESSING APPARATUS, EXPOSURE METHOD, EXPOSURE APPARATUS, ARTICLE MANUFACTURING METHOD, DECISION METHOD, AND NON-TRANSITORY COMPUTER-READABLE STORAGE MEDIUM

(71) Applicant: CANON KABUSHIKI KAISHA, Tokyo (JP)

(72) Inventor: Yoshihiro OMAMEUDA, Tochigi (JP)

(21) Appl. No.: 19/267,712

(22) Filed: Jul. 14, 2025

(30) Foreign Application Priority Data
Jul. 26, 2024 (JP) 2024-121294

(51) Int. Cl. G03F 9/00; G03F 7/00

(52) U.S. Cl. CPC G03F 9/7046; G03F 7/70633; G03F 9/7088; G03F 9/7092

(57) ABSTRACT

A method for obtaining a position of each of a plurality of regions on a substrate, including calculating an estimated position using each of a plurality of different calculation methods from position measurement data of a mark provided in a sample region of the plurality of regions, for each of the plurality of regions, obtaining a comparison result of comparing the estimated position of each of the plurality of regions calculated in the calculating and an actual position of each of the plurality of regions, for each of the plurality of calculation methods, and selecting the calculation method used to calculate the estimated position of the region from the plurality of calculation methods based on the comparison result obtained in the obtaining, for each of the plurality of regions.

### BACKGROUND

### Field of the Technology

The present disclosure relates to a method of obtaining the position of each of a plurality of regions on a substrate, an information processing apparatus, an exposure method, an exposure apparatus, an article manufacturing method, a decision method, and a non-transitory computer-readable storage medium.

### Description of the Related Art

An exposure apparatus overlays 10 or more layers of patterns (circuit patterns) and transfers these to a substrate. If the overlay accuracy between the layers is not high, inconvenience may occur in the circuit characteristic. In this case, a chip cannot satisfy a predetermined characteristic and becomes defective, resulting in a low yield. It is therefore necessary to accurately position (align) each of the plurality of regions (shot regions) to be exposed and the pattern of an original on the substrate.

In the exposure apparatus, an alignment mark arranged in each region on the substrate is detected, and each region on the substrate is aligned with the pattern of the original based on the position information of the alignment mark and the position information of the pattern of the original. Ideally, when alignment mark detection is performed for all regions on the substrate, most accurate alignment can be performed. However, this is not realistic from the viewpoint of productivity. To cope with this, the current mainstream of an alignment method for a substrate and an original is a global alignment method as disclosed in Japanese Patent Laid-Open No. 62-84516.

In the global alignment method, assuming that the relative position of each region on a substrate can be expressed by a function model of the position coordinates of the region, the positions of alignment marks arranged in a plurality of sample regions on the substrate are measured. Next, the parameter of the function model are estimated, using regression analysis-like statistic operation processing, from the assumed function model and the measurement result of the alignment mark positions. Using the parameter and the function model, the position coordinates of each region on a stage coordinate system (the array of the regions on the substrate) are calculated, thereby performing alignment. As disclosed in Japanese Patent Laid-Open No. 6-349705, in the global alignment method, a polynomial model using stage coordinates as variables is used in general, and scaling that is a first-order polynomial of stage coordinates, rotation, uniform offset, and the like are mainly used. A technique using a regression model that considers, as a parameter, even a high-order component of the array of regions on the substrate is also proposed in Japanese Patent No. 3230271.

In the conventional technique, however, as a calculation method of calculating the position (coordinates) of each region on the substrate, one function model is applied to the entire substrate. More specifically, a plurality of types of calculation methods of calculating the position of each region on the substrate are prepared, and one optimum calculation method evaluated for the entire substrate is applied to the entire substrate. Hence, there exist a case where the calculation method applied to the entire substrate is suitable and a case where not depending on the region on the substrate, and the calculation method is not necessarily optimum.

### SUMMARY

The present disclosure provides a technique advantageous in obtaining the position of each of a plurality of regions on a substrate.

According to one aspect of the present disclosure, there is provided a method for obtaining a position of each of a plurality of regions on a substrate, including calculating an estimated position using each of a plurality of different calculation methods from position measurement data of a mark provided in a sample region of the plurality of regions, for each of the plurality of regions, obtaining a comparison result of comparing the estimated position of each of the plurality of regions calculated in the calculating and an actual position of each of the plurality of regions, for each of the plurality of calculation methods, and selecting the calculation method used to calculate the estimated position of the region from the plurality of calculation methods based on the comparison result obtained in the obtaining, for each of the plurality of regions.

Features of the present disclosure will become apparent from the following description of embodiments with reference to the attached drawings. The following description of embodiments are described by way of example.

### BRIEF DESCRIPTION OF THE DRAWINGS

FIG. 1 is a schematic view illustrating configurations of an exposure apparatus according to an aspect of the present embodiment.

FIG. 2 is a schematic view illustrating configurations of an alignment optical system.

FIG. 3 is a flowchart for explaining exposure processing by the exposure apparatus.

FIG. 4 is a flowchart for explaining a method of obtaining the position of each of a plurality of shot regions on a substrate.

FIGS. 5A to 5C are views showing examples of comparison results obtained in step S406 shown in FIG. 4.

FIG. 6 is a view showing an example of a calculation method selected in step S408 shown in FIG. 4.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

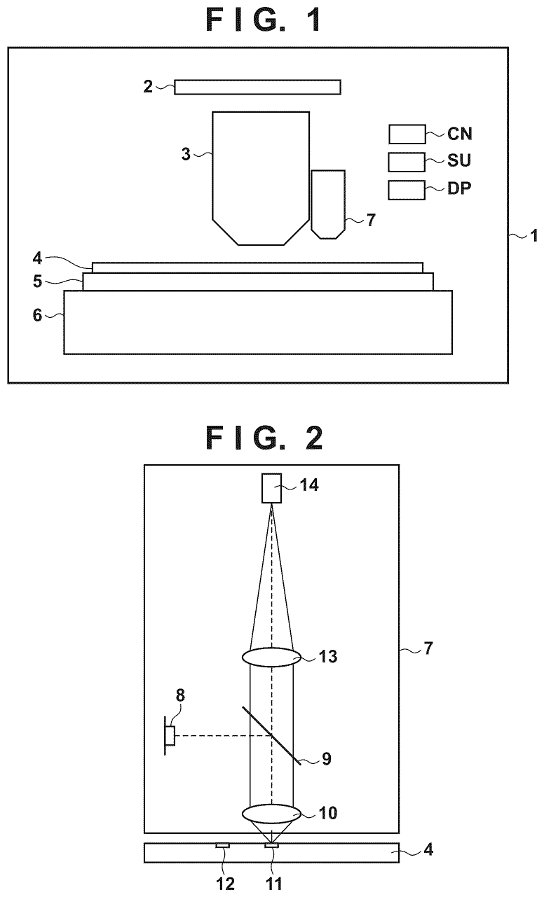

FIG. 1 is a schematic view illustrating configurations of an exposure apparatus 1 according to an aspect of the present embodiment. The exposure apparatus 1 is a lithography apparatus used in the manufacturing process of a device such as a semiconductor element, and exposes a substrate 4 via an original 2 (a reticle or a mask). In the present embodiment, the exposure apparatus 1 projects the pattern of the original 2 onto the substrate 4 via a projection optical system 3, and transfers the pattern of the original 2 to the substrate 4.

As shown in FIG. 1, the exposure apparatus 1 includes the projection optical system 3 that projects (reduction-projects) the pattern of the original 2, and a chuck 5 that holds the substrate 4 on which a base pattern or an alignment mark is formed by a preprocess. The exposure apparatus 1 also includes a substrate stage 6 that supports the chuck 5 and positions the substrate 4 at a predetermined position, an alignment optical system 7 that measures the position of an alignment mark on the substrate 4, a control unit CN, a storage unit SU, and a display unit DP.

The control unit CN is formed by, for example, a computer (information processing apparatus) including a CPU, a memory, and the like, and comprehensively controls the units of the exposure apparatus 1 in accordance with a program stored in the storage unit SU or the like, thereby operating the exposure apparatus 1. In addition to controlling exposure processing of exposing the substrate 4 via the original 2, the control unit CN functions as a processing unit that performs processing of obtaining the position of each of a plurality of shot regions (a plurality of regions) on the substrate or the array of the shot regions, that is, a so-called shot array.

The storage unit SU stores a program and various kinds of information (data) necessary to execute exposure processing of exposing the substrate 4 by controlling the units of the exposure apparatus 1. The storage unit SU also stores a program and various kinds of information (data) necessary to obtain the position of each of the plurality of shot regions on the substrate or the shot array.

The display unit DP is a display apparatus used to display various kinds of information regarding the exposure apparatus 1. The display unit DP includes, for example, a touch panel, displays various kinds of user interfaces (screens), and accepts operations from the user. Note that the display unit DP may be formed (in a common housing) integrally with the exposure apparatus 1, or may be formed (in another housing) separately from the exposure apparatus 1.

FIG. 2 is a schematic view illustrating configurations of the alignment optical system 7. The alignment optical system 7 functions as an obtaining unit that optically detects a mark (alignment mark) provided in each shot region on the substrate 4 and obtains position measurement data. In the present embodiment, the alignment optical system 7 includes a light source 8, a beam splitter 9, lenses 10 and 13, and a sensor 14. Light from the light source 8 is reflected by the beam splitter 9 and illuminates, via the lens 10, an alignment mark 11 or 12 formed on the substrate 4. The light diffracted by the alignment mark 11 or 12 is received by the sensor 14 via the lens 10, the beam splitter 9, and the lens 13.

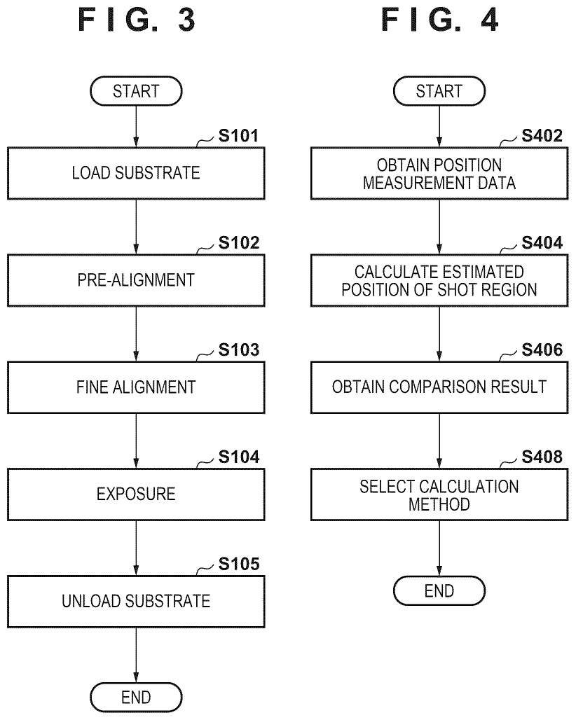

Exposure processing by the exposure apparatus 1 will be described with reference to FIG. 3. The steps until the substrate 4 is aligned and exposed will be described here.

In step S101, the substrate 4 is loaded into the exposure apparatus 1. The substrate 4 loaded into the exposure apparatus 1 is held by the chuck 5 supported by the substrate stage 6.

In step S102, pre-alignment is executed. More specifically, the alignment mark 11 for pre-alignment on the substrate 4 is detected by the alignment optical system 7, thereby roughly obtaining the position of the substrate 4. At this time, detection of the alignment mark 11 is performed for a plurality of shot regions on the substrate 4, and the shift and the first-order linear component (magnification or rotation) of the entire substrate 4 are obtained.

In step S103, fine alignment is executed. More specifically, first, based on the result of pre-alignment, the substrate stage 6 is driven to a position where the alignment mark 12 for fine alignment on the substrate can be detected by the alignment optical system 7. Then, the alignment mark 12 provided in each of the plurality of shot regions on the substrate 4 is detected by the alignment optical system 7, and the shift and the first-order linear component (magnification or rotation) of the entire substrate 4 are accurately obtained. At this time, by measuring the positions of a large number of shot regions, the high-order deformation component of (the shot array of) the substrate 4 can accurately be obtained. Thus, the accurate position of each shot region on the substrate 4, that is, the shot array can be obtained.

In step S104, the substrate 4 is exposed. More specifically, based on the shot array obtained by fine alignment, each shot region on the substrate 4 is exposed while positioning the substrate 4 via the substrate stage 6. Thus, the pattern of the original 2 is transferred to each shot region on the substrate 4 via the projection optical system 3. In step S105, the substrate 4 is unloaded from the exposure apparatus 1.

In the present embodiment, in a case where distortion (for example, a high-order deformation component) occurs in the substrate 4, a correction function concerning the distortion of the substrate 4 is provided in fine alignment (step S103). To implement the correction function, in the present embodiment, as a model (regression model) used to estimate the position of each of the plurality of shot regions (shot array) on the substrate, a quintic polynomial model will be described as an example, but the model is not limited to this. For example, a model of an arbitrary degree may be used, or a model (a triangle function model, a logarithmic model, or the like) other than a polynomial may be used as the model.

When the deformation of the substrate 4 is expressed by a quintic polynomial model, the position of each shot region, more specifically, the positional shifts (ShiftX, ShiftY) of each shot region are expressed by equations below. Note that the positional shift of each shot region is a correction value (alignment correction value) used to perform correction concerning the positional shift.

$$ShiftX = {k}_{1} + {k}_{3} x + {k}_{5} y + {k}_{7} {x}^{2} + {k}_{9} xy + {k}_{11} {y}^{2} + {k}_{13} {x}^{3} + {k}_{15} {x}^{2} y + {k}_{17} {xy}^{2} + {k}_{19} {y}^{3} + {k}_{21} {x}^{4} + {k}_{23} {x}^{3} y + {k}_{25} {x}^{2} {y}^{2} + {k}_{27} {xy}^{3} + {k}_{29} {y}^{4} + {k}_{31} {x}^{5} + {k}_{33} {x}^{4} y + {k}_{35} {x}^{3} {y}^{2} + {k}_{37} {x}^{2} {y}^{3} + {k}_{39} {xy}^{4} + {k}_{41} {y}^{5}$$

$$ShiftY = {k}_{2} + {k}_{4} y + {k}_{6} x + {k}_{8} {y}^{2} + {k}_{10} xy + {k}_{12} {x}^{2} + {k}_{14} {y}^{3} + {k}_{16} {xy}^{2} + {k}_{18} {x}^{2} y + {k}_{20} {x}^{3} + {k}_{22} {x}^{4} + {k}_{24} {xy}^{3} y + {k}_{26} {x}^{2} {y}^{2} + {k}_{28} {x}^{3} y + {k}_{30} {x}^{4} + {k}_{32} {y}^{5} + {k}_{34} {xy}^{4} y + {k}_{36} {x}^{2} {y}^{3} + {k}_{38} {x}^{3} {y}^{2} + {k}_{40} {x}^{4} y + {k}_{42} {x}^{5}$$

In the equations, x and y indicate the positions of each shot region on the substrate 4. Coefficients k₁ to k₄₂ in the equations are decided from the actual position measurement data of each shot region on the substrate 4. Then, the positional shift of each shot region is obtained based on the equations with the decided coefficients. The position of the entire substrate 4 is corrected based on the thus obtained positional shift of each shot region.

To obtain position measurement data, the alignment optical system 7 detects the alignment marks 12 provided in some shot regions, that is, so-called sample regions among the plurality of shot regions on the substrate. The number of sample regions is about 4 to 50. Since a higher-order deformation component of the substrate 4 can be corrected by increasing the number of sample regions, more accurate alignment can be performed.

Here, in the conventional technique, as a calculation method of calculating the position (estimated position) of each shot region on the substrate, one model is applied to the entire substrate 4. Concerning each shot region, this model is not necessarily optimum.

In the present embodiment, the model that is the calculation method of calculating the estimated position of a shot region is optimized for each shot region on the substrate, and the calculation method used to calculate the estimated position of the shot region is changed between the shot regions. In other words, for each of the plurality of shot regions on the substrate, a calculation method used to calculate a shot region is selected (decided) from a plurality of calculation methods.

A method for obtaining the position of each of the plurality of shot regions on the substrate in the present embodiment will be described below with reference to FIG. 4, focusing on deciding the calculation method of calculating the estimated position. In the present embodiment, the method is executed by the control unit CN of the exposure apparatus 1, but may be executed by an information processing apparatus that is an external apparatus different from the exposure apparatus 1.

In step S402, the position measurement data of a mark provided in each of the plurality of shot regions on the substrate is obtained. As described above, the position measurement data can be obtained by the alignment optical system 7 optically detecting a mark provided in each shot region on the substrate 4.

In step S404 (first step), the estimated position of each of the plurality of shot regions on the substrate is calculated from the position measurement data obtained in step S402 using a calculation method of calculating (estimating) the estimated position of a shot region. More specifically, the position measurement data of a mark provided in a sample region is extracted from the position measurement data obtained in step S402, and the estimated position of each of the plurality of shot regions on the substrate is calculated from the position measurement data using each of a plurality of different calculation methods.

In the present embodiment, using a cubic polynomial model and a quintic polynomial model as the plurality of calculation methods, the estimated position of each shot region on the substrate is calculated using each model. For example, the position measurement data of the mark provided in the sample region, which is obtained in step S402, is applied to each of the cubic polynomial model and the quintic polynomial model, thereby obtaining the positional shift of each shot region as the estimated position of each shot region on the substrate.

In step S406 (second step), for each of the plurality of calculation methods, a comparison result of comparing the estimated position of each of the plurality of shot regions calculated in step S404 and the actual position (the actual position of each of the plurality of shot regions) is obtained. As the comparison result, for example, the difference between the estimated position of each of the plurality of shot regions and the actual position of each of the plurality of shot regions may be used. Since the position measurement data of the mark provided in each of the plurality of shot regions on the substrate is obtained in step S402, the actual position of each of the plurality of shot regions can be obtained from the position measurement data. Also, as the comparison result, a correction result obtained by performing correction concerning the positional shift of each of the plurality of shot regions based on the estimated position of each of the plurality of shot regions may be used.

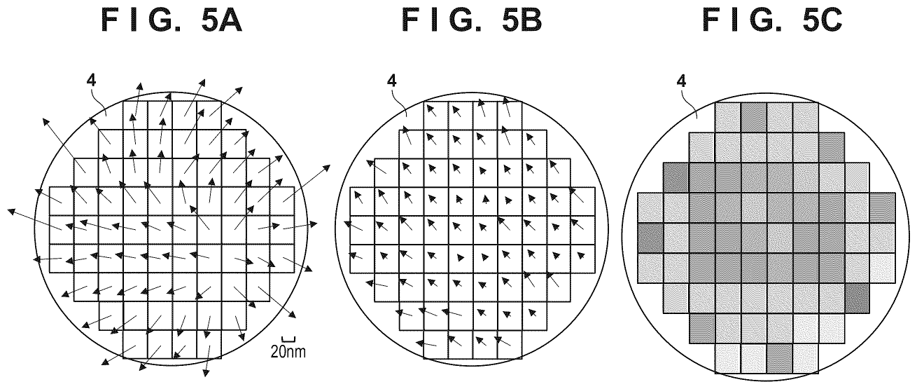

In the present embodiment, for the cubic polynomial model, as shown in FIG. 5A, a correction result is obtained by performing correction concerning the positional shift of each shot region based on the estimated position (alignment correction value) of each shot region calculated using the cubic polynomial model. Similarly, for the quintic polynomial model, as shown in FIG. 5B, a correction result is obtained by performing correction concerning the positional shift of each shot region based on the estimated position (alignment correction value) of each shot region calculated using the quintic polynomial model. In FIGS. 5A and 5B, a correction result is as a correction residual that is the difference between the estimated position of each shot region and the actual position of each shot region, and is expressed by the length and direction of an arrow in each shot region. Thus, in the present embodiment, for each of the cubic polynomial model and the quintic polynomial model (different two calculation methods), a correction residual that is a correction result for each shot region is obtained as a comparison result. Note that in step S406, as shown in FIG. 5C, the difference between the correction residual shown in FIG. 5A and the correction residual shown in FIG. 5B may further be obtained. Also, to allow the user to visually recognize the difference between the correction residuals (correction results) due to the difference of the calculation method, the correction residuals shown in FIGS. 5A and 5B or the difference shown in FIG. 5C may be displayed on the display unit DP of the exposure apparatus 1.

In step S408 (third step), for each of the plurality of shot regions on the substrate, a calculation method used to calculate the estimated position of the shot region is selected (decided) from the plurality of calculation methods based on the comparison result obtained in step S406. For example, for each shot region, a calculation method in which the difference between the estimated position and the actual position of the shot region falls within an allowable range, preferably, a calculation method in which the difference is smallest is selected from the plurality of calculation methods as the calculation method used to calculate the estimated position of the shot region.

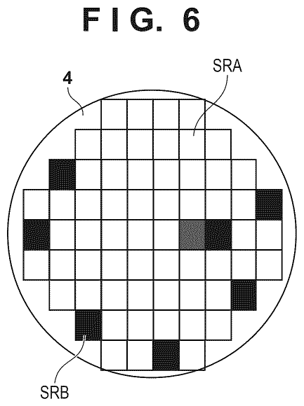

In the present embodiment, the correction residual shown in FIG. 5A and the correction residual shown in FIG. 5B are compared for each shot region, and the polynomial model corresponding to the small correction residual, that is, the shorter arrow is selected. When the cubic polynomial model or the quintic polynomial model is thus selected as the calculation method for each shot region, as shown in FIG. 6, the cubic polynomial model is selected for a shot region SRA, and the quintic polynomial model is selected for a shot region SRB.

According to the present embodiment, since it is possible to select (the model that is) the calculation method optimum for each of the plurality of shot regions on the substrate and calculate the estimated position close to the actual position of a shot region, the alignment accuracy can be improved.

In the present embodiment, the unit of a region to select (decide) the calculation method used to calculate the estimated position of each shot region is a shot region. However, the present disclosure is not limited to this, and the calculation method can be applied to an arbitrary region on the substrate. For example, the calculation method used to calculate the estimated position of a shot region may be selected for each mark region where a mark (alignment mark 11 or 12) on the substrate is provided. Alternatively, the calculation method used to calculate the estimated position of a shot region may be selected for each specific region on the substrate. Here, the specific region on the substrate is a region whose feature is different from other regions and is, for example, an outer peripheral region including the outer periphery of the substrate 4. Note that the same (common) calculation method may be selected for specific regions on the substrate, and the calculation methods may individually be selected for the other regions.

In addition, the comparison result obtained by comparing the estimated position and the actual position of each shot region on the substrate may be the comparison result of one of the shift component, the magnification component, and the rotation component of the positional shift between these or the comparison result of the combination of the shift component, the magnification component, and the rotation component.

Also, a weight according to each of the plurality of calculation methods may be given to the comparison result obtained by comparing the estimated position and the actual position of each shot region on the substrate. When the calculation method used to calculate the estimated position of each shot region is selected based on the thus obtained weighted comparison result, it is possible to suppress occurrence of variations in the selected calculation method, which is caused by a slight difference between the calculation methods. Also, if a specific calculation method is effective, the weight to the specific calculation method is made large, thereby preferentially selecting the specific calculation method. For example, if a high-order calculation method has high reliability, the weight to the high-order calculation method is made large, thereby selecting the high-order calculation method in many cases. Note that a threshold may be provided for the comparison result obtained by comparing the estimated position and the actual position of each shot region on the substrate, and the calculation method used to calculate the estimated position of each shot region may be selected by comparison with the threshold.

In addition, the plurality of calculation methods may be calculation methods of different types or may be calculation methods in which parameters of the same type are different. For example, if the calculation methods are considered to be polynomials used to estimate the position of each shot region, the plurality of calculation methods include calculation methods in which polynomial types are different or calculation methods in which parameters of the polynomial are different. If a hyper parameter is different, some coefficients of the polynomial may be removed, or the weight may be changed. More specifically, the parameter may be changed by giving a weight to a specific term of the polynomial. When generating a model (regression model) using machine learning or the like, the hyper parameter thereof may be changed.

An article manufacturing method according to the present embodiment is suitable for manufacturing an article, for example, a semiconductor element, a liquid crystal display element, a flat panel display, or a MEMS. The manufacturing method includes a process of exposing, using the above-described exposure apparatus 1 (exposure processing), a substrate to which a photoresist is applied, and a process of developing the exposed photoresist. In addition, an etching process, an ion implantation process, and the like are performed for the substrate using the pattern of the developed photoresist as a mask, thereby forming a circuit pattern on the substrate. By repeating the processes of exposure, development, etching, and the like, a circuit pattern formed by a plurality of layers is formed on the substrate. In the post-process, dicing (processing) is performed for the substrate on which the circuit pattern is formed, and chip mounting, bonding, and inspection processes are performed. The manufacturing method can also include other known processes (for example, oxidation, deposition, vapor deposition, doping, planarization, and resist removal). The method of manufacturing an article according to this embodiment is advantageous in at least one of the performance, quality, productivity, and production cost of the article, as compared to conventional methods.

According to the present disclosure, it is possible to provide a technique advantageous in, for example, obtaining the position of each of a plurality of regions on a substrate.

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent application No. 2024-121294 filed on Jul. 26, 2024, which is hereby incorporated by reference herein in its entirety.

What is claimed is:

1. A method for obtaining a position of each of a plurality of regions on a substrate, comprising:
calculating an estimated position using each of a plurality of different calculation methods from position measurement data of a mark provided in a sample region of the plurality of regions, for each of the plurality of regions;
obtaining a comparison result of comparing the estimated position of each of the plurality of regions calculated in the calculating and an actual position of each of the plurality of regions, for each of the plurality of calculation methods; and
selecting the calculation method used to calculate the estimated position of the region from the plurality of calculation methods based on the comparison result obtained in the obtaining, for each of the plurality of regions.

2. The method according to claim 1, wherein the region includes a shot region on the substrate, a mark region where a mark on the substrate is provided, or a specific region on the substrate.

3. The method according to claim 1, wherein the comparison result includes a difference between the estimated position of each of the plurality of regions and the actual position of each of the plurality of regions.

4. The method according to claim 1, wherein the comparison result includes one of a shift component, a magnification component, and a rotation component of a positional shift between the estimated position of each of the plurality of regions and the actual position of each of the plurality of regions.

5. The method according to claim 1, wherein the comparison result includes a combination of a shift component, a magnification component, and a rotation component of a positional shift between the estimated position of each of the plurality of regions and the actual position of each of the plurality of regions.

6. The method according to claim 3, wherein in the selecting a calculation method in which the difference is smallest is selected from the plurality of calculation methods as the calculation method used to calculate the estimated position of the region, for each of the plurality of regions.

7. The method according to claim 1, wherein in the selecting the calculation method used to calculate the estimated position of the region is selected based on a weighted comparison result obtained by giving a weight according to each of the plurality of calculation methods to the comparison result obtained in the obtaining, for each of the plurality of regions.

8. The method according to claim 1, wherein the plurality of calculation methods include calculation methods in which types of polynomials used to estimate the position of each of the plurality of regions are different or calculation methods in which parameters of the polynomials used to estimate the position of each of the plurality of regions are different.

9. The method according to claim 1, wherein the obtaining includes obtaining the actual position of each of the plurality of regions from position measurement data of a mark provided in each of the plurality of regions.

10. The method according to claim 1, wherein in the obtaining, a correction result obtained by performing correction concerning a positional shift of each of the plurality of regions based on the estimated position calculated in the calculating is obtained.

11. The method according to claim 10, wherein the correction result includes a correction residual that is a difference between the estimated position of each of the plurality of regions and the actual position of each of the plurality of regions.

12. An information processing apparatus comprising
a processing unit configured to perform processing for obtaining a position of each of a plurality of regions on a substrate,
wherein the processing unit performs:
calculating an estimated position using each of a plurality of different calculation methods from position measurement data of a mark provided in a sample region of the plurality of regions, for each of the plurality of regions;
obtaining a comparison result of comparing the estimated position of each of the plurality of regions calculated in the calculating and an actual position of each of the plurality of regions, for each of the plurality of calculation methods; and
selecting the calculation method used to calculate the estimated position of the region from the plurality of calculation methods based on the comparison result obtained in the obtaining, for each of the plurality of regions.

13. An exposure method of exposing a substrate, comprising:
obtaining a position of each of a plurality of regions on the substrate; and
exposing each of the plurality of regions while positioning the substrate based on the position obtained in the obtaining the position,
wherein the obtaining the position includes:
calculating an estimated position using each of a plurality of different calculation methods from position measurement data of a mark provided in a sample region of the plurality of regions, for each of the plurality of regions;
obtaining a comparison result of comparing the estimated position of each of the plurality of regions calculated in the calculating and an actual position of each of the plurality of regions, for each of the plurality of calculation methods; and
selecting the calculation method used to calculate the estimated position of the region from the plurality of calculation methods based on the comparison result obtained in the obtaining, for each of the plurality of regions.

14. An exposure apparatus for exposing a substrate, comprising:
an obtaining unit configured to obtain position measurement data of a mark provided in a sample region of a plurality of regions on the substrate; and
a processing unit configured to perform processing of obtaining a position of each of the plurality of regions using the position measurement data obtained by the obtaining unit,
wherein the processing unit performs:
calculating an estimated position using each of a plurality of different calculation methods from the position measurement data, for each of the plurality of regions;
obtaining a comparison result of comparing the estimated position of each of the plurality of regions calculated in the calculating and an actual position of each of the plurality of regions, for each of the plurality of calculation methods; and
selecting the calculation method used to calculate the estimated position of the region from the plurality of calculation methods based on the comparison result obtained in the obtaining, for each of the plurality of regions.

15. An article manufacturing method comprising:
exposing a substrate using an exposure method defined in claim 13;
developing the substrate exposed in the exposing; and
manufacturing an article from the substrate developed in the developing.

16. A decision method of deciding a calculation method of calculating an estimated position of each of a plurality of regions on a substrate, comprising:
calculating an estimated position using each of a plurality of different calculation methods from position measurement data of a mark provided in a sample region of the plurality of regions, for each of the plurality of regions;
obtaining a comparison result of comparing the estimated position of each of the plurality of regions calculated in the calculating and an actual position of each of the plurality of regions, for each of the plurality of calculation methods; and
selecting the calculation method used to calculate the estimated position of the region from the plurality of calculation methods based on the comparison result obtained in the obtaining, for each of the plurality of regions.

17. An information processing apparatus comprising
a processing unit configured to perform processing for deciding a calculation method of calculating an estimated position of each of a plurality of regions on a substrate,
wherein the processing unit performs:
calculating an estimated position using each of a plurality of different calculation methods from position measurement data of a mark provided in a sample region of the plurality of regions, for each of the plurality of regions;
obtaining a comparison result of comparing the estimated position of each of the plurality of regions calculated in the calculating and an actual position of each of the plurality of regions, for each of the plurality of calculation methods; and
selecting the calculation method used to calculate the estimated position of the region from the plurality of calculation methods based on the comparison result obtained in the obtaining, for each of the plurality of regions.

18. A non-transitory computer-readable storage medium storing a program configured to cause a computer to execute a method defined in claim 1.

19. A non-transitory computer-readable storage medium storing a program configured to cause a computer to execute a decision method defined in claim 16.
